(19) United States
(12) Patent Application Publication
(10) Pub. No.: US 2025/0132172 A1
(43) Pub. Date: Apr. 24, 2025

(54) SUBSTRATE PROCESSING APPARATUS AND SUBSTRATE PROCESSING METHOD

(71) Applicant: SEMES CO., LTD., Cheonan-si (KR)

(72) Inventors: Tae Jong CHOI, Asan-si (KR); Yong Hee LEE, Cheonan-si (KR); Jong Doo LEE, Cheonan-si (KR)

(73) Assignee: SEMES CO., LTD., Cheonan-si (KR)

(21) Appl. No.: 18/918,497

(22) Filed: Oct. 17, 2024

(30) Foreign Application Priority Data
Oct. 24, 2023 (KR) 10-2023-0142720

(51) Int. Cl. H01L 21/67; H01L 21/02

(52) U.S. Cl. CPC H01L 21/67034; H01L 21/02101

(57) ABSTRACT

Disclosed is an apparatus for processing a substrate, the apparatus including: a body providing a processing space; a supply line for supplying a drying fluid that removes a treatment fluid on a substrate supported in the processing space; an exhaust line for exhausting an atmosphere of the processing space; and a fluid circulation unit connected with the exhaust line and the supply line, in which the fluid circulation unit includes: a separator for separating the treatment fluid and the drying fluid from a mixed fluid in which the treatment fluid and the drying fluid exhausted from the processing space are mixed; and a liquid reuse line connected to the separator, and for withdrawing, from the separator, the treatment fluid separated from the separator.

### CROSS-REFERENCE TO RELATED APPLICATIONS

This application claims priority to and the benefit of Korean Patent Application No. 10-2023-0142720 filed in the Korean Intellectual Property Office on Oct. 24, 2023, the entire contents of which are incorporated herein by reference.

### TECHNICAL FIELD

The present invention relates to a substrate processing apparatus and a substrate processing method.

### BACKGROUND ART

To manufacture a semiconductor device, a desired pattern is formed on a substrate, such as a wafer, through various processes, such as photography, etching, ashing, ion implantation, and thin film deposition. Various treatment solutions and treatment gas are used in each process, and particles and process by-products are generated during the process. Cleaning processes are performed before and after each process to remove these particles and process by-products from the substrate.

A typical cleaning process includes liquid-processing the substrate with a chemical and a rinse solution. The substrate is then dried to remove any residual chemicals and rinse solution on the substrate. One example of a drying treatment is a rotary drying process in which the substrate is rotated at high speeds to remove any residual rinse solution on the substrate. However, the rotary drying method may disrupt the pattern formed on the substrate.

Recently, a supercritical drying process has been utilized in which the residual rinse solution on the substrate is replaced with an organic solvent, such as isopropyl alcohol (IPA), which has a low surface tension, by supplying the organic solvent on the substrate and the substrate is then supplied with supercritical drying gas (for example, carbon dioxide) to remove the residual organic solvent from the substrate. In the supercritical drying process, the drying gas is supplied to a process chamber with the sealed interior, and the drying gas is heated and pressurized. Both the temperature and the pressure of the drying gas rise to the critical point or above, and the drying gas undergoes a phase change to the supercritical state.

The supercritical phase-change drying gas is supplied to the substrate to remove any residual organic solvents on the substrate. The organic solvent removed from the substrate is suspended in the space within the process chamber and discharged to the outside of the process chamber as the space within the process chamber is exhausted. Since organic solvents suspended in the process chamber may re-contaminate the substrate, it is demanded to reduce the concentration of organic solvents in the process chamber.

Typically, to reduce the concentration of organic solvent in the process chamber, drying gas is continuously supplied to the process chamber. However, this method has a very high consumption of drying gas.

### SUMMARY OF THE INVENTION

The present invention has been made in an effort to provide a substrate processing apparatus and a substrate processing method that are capable of minimizing the amount of treatment solution and drying fluid consumed and discarded during the process of processing a substrate.

The present invention has also been made in an effort to provide a substrate processing apparatus and a substrate processing method that are capable of minimizing the amount of unused treatment solution and drying fluid supplied to a substrate in the process of processing the substrate.

The present invention has also been made in an effort to provide a substrate processing apparatus and a substrate processing method that are capable of effectively separating a treatment solution and a drying fluid from a mixed fluid of the treatment solution and the drying fluid.

The object of the present invention is not limited thereto, and other objects not mentioned will be clearly understood by those of ordinary skill in the art from the following description.

An exemplary embodiment of the present invention provides an apparatus for processing a substrate, the apparatus including: a body providing a processing space; a supply line for supplying a drying fluid that removes a treatment fluid on a substrate supported in the processing space; an exhaust line for exhausting an atmosphere of the processing space; and a fluid circulation unit connected with the exhaust line and the supply line, in which the fluid circulation unit includes: a separator for separating the treatment fluid and the drying fluid from a mixed fluid in which the treatment fluid and the drying fluid exhausted from the processing space are mixed; and a liquid reuse line connected to the separator, and for withdrawing, from the separator, the treatment fluid separated from the separator.

According to the exemplary embodiment, the apparatus may further include a liquid treating chamber for supplying the treatment fluid to the substrate, in which the liquid reuse line may be connected to the liquid treating chamber.

According to the exemplary embodiment, the fluid circulation unit may include: a first circulation line connected to the exhaust line and the separator; and a second circulation line connected with the separator and the supply line, and a cross-sectional area of a separation space provided by the separator may be greater than a cross-sectional area of the first circulation line.

According to the exemplary embodiment, the separator may include: a separation housing providing the separation space; and a cooling unit provided in the separation housing.

According to the exemplary embodiment, a cooling airflow or cooling water may flow in the cooling unit.

According to the exemplary embodiment, in the first circulation line, an orifice may be installed to maintain a constant pressure difference between a front end and a rear end.

According to the exemplary embodiment, the first circulation line may be connected to the exhaust line upstream of an exhaust valve installed on the exhaust line.

According to the exemplary embodiment, in the second circulation line, a fluid pressurizer may be installed for withdrawing and pressurizing the drying fluid separated from the mixed fluid in the separation space.

According to the exemplary embodiment, in the supply line, a heater may be installed to heat the drying fluid supplied to the processing space, and the second circulation line may be connected to the supply line upstream of the heater.

According to the exemplary embodiment, the supply line may include: a first supply line for supplying the drying fluid to a first region of the processing space; and a second supply line for supplying the drying fluid to a second region of the processing space at a location different from the first region of the processing space, and the second circulation line may be branched to be connected to the first supply line and the second supply line, respectively.

Another exemplary embodiment of the present invention provides a method of processing a substrate, the method including: a liquid treatment operation of supplying a treatment solution to a substrate and processing the substrate in a liquid treating chamber; and a drying operation of removing the treatment solution remaining on the substrate by supplying a drying fluid onto the substrate in a drying chamber, in which the drying operation includes exhausting a mixed fluid including the drying fluid and the treatment solution from a processing space provided by the drying chamber, and separating the drying fluid and the treatment solution included in the exhausted mixed fluid, and at least a portion of the treatment solution separated from the mixed fluid is supplied to the liquid treating chamber.

According to the exemplary embodiment, at least a portion of the drying fluid separated from the mixed fluid may be supplied back into the processing space.

According to the exemplary embodiment, the drying operation may include: a pressurization operation of supplying the drying fluid to the processing space provided by the drying chamber to increase a pressure of the processing space to a set pressure; after the pressurization operation, a flow operation of causing the drying fluid supplied to the processing space to flow and removing the treatment solution supplied onto the substrate; and after the flow operation, a depressurization operation of reducing the pressure of the processing space, and at least a portion of the drying fluid separated from the mixed fluid is supplied back into the processing space during the flow operation.

According to the exemplary embodiment, at least a portion of the drying fluid separated from the mixed fluid may be pressurized by a fluid pressurizer and supplied back into the processing space.

According to the exemplary embodiment, the drying operation may include: a pressurization operation of supplying the drying fluid to the processing space provided by the drying chamber to increase a pressure of the processing space to a set pressure; after the pressurization operation, a flow operation of causing the drying fluid supplied to the processing space to flow and removing the treatment solution supplied onto the substrate; and after the flow operation, a depressurization operation of reducing the pressure of the processing space, and at least a portion of the drying fluid separated from the mixed fluid may be supplied to a supply line that supplies the drying fluid to the processing space in the depressurization operation.

According to the exemplary embodiment, the mixed fluid exhausted from the processing space may be introduced into a fluid circulation unit connected to an exhaust line exhausting the processing space and a supply line supplying the drying fluid to the processing space, and the fluid circulation unit may depressurize and cool the mixed fluid to separate the drying fluid and the treatment solution.

According to the exemplary embodiment, the fluid circulation unit may depressurize the mixed fluid by causing the mixed fluid to flow from a circulation line having a first cross-sectional area to a separation space of a separation housing having a second cross-sectional area greater than the first cross-sectional area, and cool the mixed fluid by cooling the separation space.

Still another exemplary embodiment of the present invention provides an apparatus for processing a substrate, the apparatus including: a plurality of liquid treating chambers for liquid-treating a substrate by supplying a treatment solution to the substrate; and a drying chamber for removing the treatment solution supplied to the substrate from any one of the plurality of liquid treating chambers, in which the drying chamber includes: a body providing a processing space; a supply line for supplying a drying fluid that removes the treatment solution on the substrate supported in the processing space; an exhaust line for exhausting an atmosphere of the processing space; and a fluid circulation unit connected with the exhaust line and the supply line, and the fluid circulation unit includes: a separator for separating the treatment solution and the drying fluid from a mixed fluid in which the treatment solution and the drying fluid exhausted from the processing space are mixed, the separator including: a separation housing providing the separation space; and a cooling unit provided on an exterior of the separation housing; and a liquid reuse line connected to the separator, and for withdrawing the separated treatment solution from the separator and supplying the withdrawn treatment solution to any of the plurality of liquid treating chambers, and connected to a lower portion of the separation housing.

According to the exemplary embodiment, the fluid circulation unit may further include: a first circulation line connected with the exhaust line and the separator; a second circulation line connected with the separator and the supply line and connected to an upper portion of the separation housing; an orifice installed in the first circulation line, and maintaining a constant pressure difference between a front end and a rear end; a fluid pressurizer installed in the second circulation line, and for withdrawing and pressurizing the drying fluid separated from the mixed fluid in the separation space; and a filter installed downstream of the fluid pressurizer in the second circulation line.

According to the exemplary embodiment, in the supply line, a heater may be installed to heat the drying fluid supplied to the processing space, and the second circulation line may be connected to the supply line upstream of the heater.

According to the exemplary embodiment of the present invention, the amount of treatment solution and drying fluid consumed and discarded in the process of processing the substrate may be minimized.

Furthermore, according to the exemplary embodiment of the present invention, the amount of unused treatment solution and drying fluid supplied to the substrate during the process of processing the substrate may be minimized.

Further, according to the exemplary embodiment of the present invention, the treatment solution and the drying fluid may be effectively separated from a mixed fluid of the treatment solution and the drying fluid.

The effect of the present invention is not limited to the foregoing effects, and those skilled in the art may clearly understand non-mentioned effects from the present specification and the accompanying drawings.

### BRIEF DESCRIPTION OF THE DRAWINGS

FIG. 1 is a top plan view schematically illustrating a substrate processing apparatus according to an exemplary embodiment of the present invention.

FIG. 2 is a diagram schematically illustrating a liquid treating chamber of FIG. 1 according to an exemplary embodiment.

FIG. 3 is a diagram schematically illustrating a drying chamber of FIG. 1 according to the exemplary embodiment.

FIG. 4 is a diagram illustrating a structure of a separator of FIG. 3.

FIG. 5 is a flow chart illustrating a substrate processing method according to an exemplary embodiment of the present invention.

FIG. 6 is a graph illustrating an example of a processing space pressure change during a pressurization operation, a flow operation, and a depressurization operation of FIG. 5.

FIG. 7 is a diagram illustrating a view of a drying chamber performing the pressurization operation of FIG. 6.

FIG. 8 is a diagram illustrating a view of the drying chamber performing the flow operation of FIG. 6.

FIG. 9 is a diagram illustrating a view of the drying chamber performing the depressurization operation of FIG. 5.

FIG. 10 is a graph showing different examples of processing space pressure changes during the pressurization operation, the flow operation, and the depressurization operation of FIG. 5.

FIGS. 11 and 12 are diagrams a view of the drying chamber performing the flow operation of FIG. 10.

FIG. 13 is a diagram illustrating a separator according to another exemplary embodiment of the present invention.

FIG. 14 is a diagram illustrating a drying chamber according to another exemplary embodiment of the present invention.

FIG. 15 is a diagram illustrating a drying chamber according to another exemplary embodiment of the present invention.

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

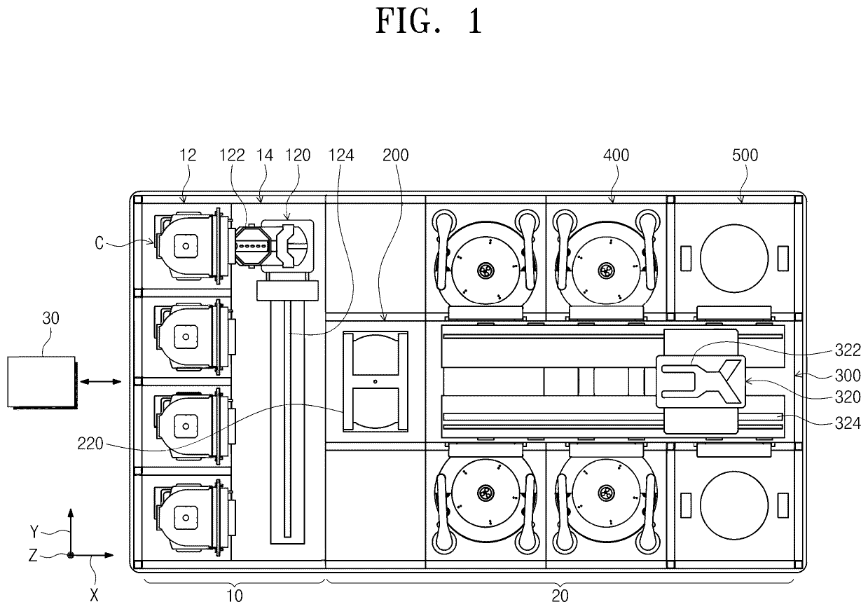

FIG. 1 is a top plan view schematically illustrating a substrate processing apparatus according to an exemplary embodiment of the present invention.

Referring to FIG. 1, a substrate processing apparatus includes an index module 10, a processing module 20, and a controller 30. When viewed from above, the index module 10 and the processing module 20 are disposed along one direction. Hereinafter, the direction in which the index module 10 and the processing module 20 are arranged is referred to as a first direction X, when viewed from above, a direction perpendicular to the first direction X is referred to as a second direction Y, and a direction perpendicular to both the first direction X and the second direction Y is referred to as a third direction Z.

The index module 10 transfers the substrate W from the container C in which the substrate W is accommodated to the processing module 20, and accommodates the substrate W that has been completely treated in the processing module 20 in the container C. A longitudinal direction of the index module 10 is provided in the second direction Y. The index module 10 includes a load port 12 and an index frame 14. Based on the index frame 14, the load port 12 is located at a side opposite to the processing module 20. The container C in which the substrates W are accommodated is placed in the load port 12. A plurality of load ports 12 may be provided, and the plurality of load ports 12 may be disposed along the second direction Y.

As the container C, an airtight container, such as a Front Open Unified Pod (FOUP), may be used. The container C may be placed on the load port 12 by a transport means (not illustrated), such as an overhead transfer, an overhead conveyor, or an automatic guided vehicle, or an operator.

An index robot 120 is provided to the index frame 14. A guide rail 124 of which a longitudinal direction is provided in the second direction Y is provided in the index frame 14, and the index robot 120 may be provided to be movable on the guide rail 124. The index robot 120 includes a hand 122 on which the substrate W is placed, and the hand 122 may be provided to be movable forward and backward directions, rotatable about the third direction Z and movable along the third direction Z. A plurality of hands 122 are provided to be spaced apart in the vertical direction, and the hands 122 may move forward and backward independently of each other.

The controller 30 may control the substrate processing apparatus. The controller 30 may include a process controller formed of a microprocessor (computer) that executes the control of the substrate processing apparatus, a user interface formed of a keyboard in which an operator performs a command input operation or the like in order to manage the substrate processing apparatus, a display for visualizing and displaying an operation situation of the substrate processing apparatus, and the like, and a storage unit storing a control program for executing the process executed in the substrate processing apparatus under the control of the process controller or a program, that is, a treatment recipe, for executing the process in each component according to various data and treatment conditions. Further, the user interface and the storage unit may be connected to the process controller. The processing recipe may be memorized in a storage medium in the storage unit, and the storage medium may be a hard disk, and may also be a portable disk, such as a CD-ROM or a DVD, or a semiconductor memory, such as a flash memory.

The controller 30 may control the substrate treatment apparatus so as to perform a substrate treatment method to be described below.

The processing module 20 includes a buffer unit 200, a transfer chamber 300, a liquid treating chamber 400, and a drying chamber 500. The buffer unit 200 provides a space in which the substrate W loaded into the processing module 20 and the substrate W unloaded from the processing module 20 stay temporarily. The liquid treating chamber 400 performs a liquid treating process of treating the substrate W with a liquid by supplying a liquid onto the substrate W. The drying chamber 500 performs a drying process of removing the liquid residual on the substrate W. The transfer chamber 300 transfers the substrate W between the buffer unit 200, the liquid treating chamber 400, and the drying chamber 500.

A longitudinal direction of the transfer chamber 300 may be provided in the first direction X. The buffer unit 200 may be disposed between the index module 10 and the transfer chamber 300. The liquid treating chamber 400 and the drying chamber 500 may be disposed on the side portion of the transfer chamber 300. The liquid treating chamber 400 and the transfer chamber 300 may be disposed along the second direction Y. The drying chamber 500 and the transfer chamber 300 may be disposed along the second direction Y. The buffer unit 200 may be located at one end of the transfer chamber 300.

According to the example, the liquid treating chambers 400 are disposed on both sides of transfer chamber 300, and the drying chambers 500 are disposed on both sides of the transfer chamber 300, and the liquid treating chambers 400 may be disposed closer to the buffer unit 200 than the drying chambers 500. At one side of the transfer chamber 300, the liquid treating chambers 400 may be provided in an arrangement of A×B (each of A and B is 1 or a natural larger than 1) in the first direction X and the third direction Z. Further, at one side of the transfer chamber 300, the drying chambers 500 may be provided in number of C×D (each of C and D is 1 or a natural number larger than 1) in the first direction 92 and the third direction 96. Unlike the above, only the liquid treating chambers 400 may be provided on one side of the transfer chamber 300, and only the drying chambers 500 may be provided on the other side of the transfer chamber 300.

The transfer chamber 300 includes a transfer robot 320. A guide rail 324 of which a longitudinal direction is provided in the first direction X is provided in the transfer chamber 300, and the transfer robot 320 may be provided to be movable on the guide rail 324. The transfer robot 320 includes a hand 322 on which the substrate W is placed, and the hand 322 may be provided to be movable forward and backward directions, rotatable about the third direction Z and movable along the third direction Z. A plurality of hands 322 are provided to be spaced apart in the vertical direction, and the hands 322 may move forward and backward independently of each other.

The buffer unit 200 includes a plurality of buffers 220 on which the substrate W is placed. The buffers 220 may be disposed to be spaced apart from each other along the third direction Z. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

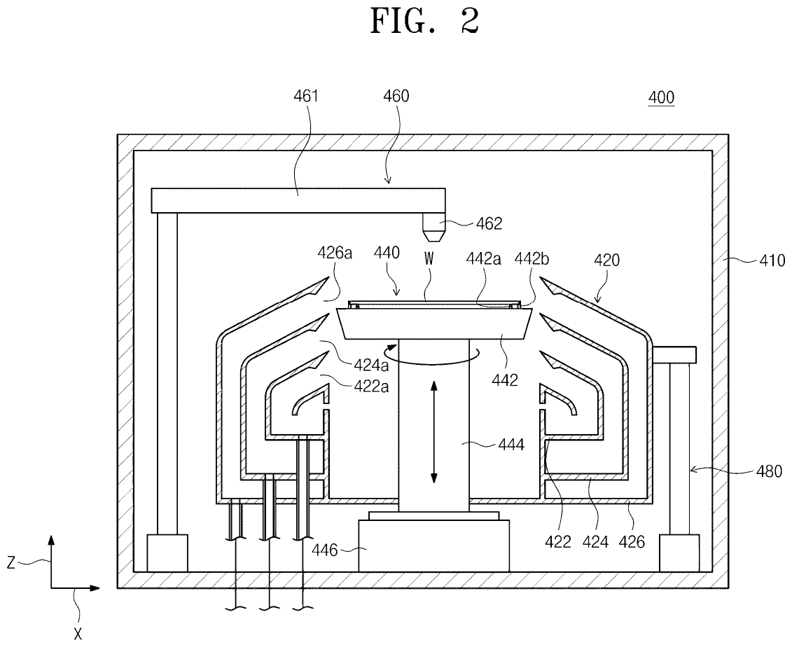

FIG. 2 is a diagram schematically illustrating a liquid treating chamber of FIG. 1 according to an exemplary embodiment. Referring to FIG. 2, the liquid treating chamber 400 includes a housing 410, a cup 420, a support unit 440, a liquid supply unit 460, and a lifting unit 480.

The housing 410 may have an interior space where the substrate W is processed. The housing 410 may have a generally hexahedral shape. For example, the housing 410 may have a cuboidal shape. Additionally, the housing 410 may have an opening (not illustrated) through which the substrate W is loaded or unloaded. Additionally, the housing 410 may be equipped with a door (not illustrated) that selectively opens and closes the opening.

The cup 420 may have a barrel shape with an open top. The cup 420 has a processing space, and the substrate W may be liquid-treated within the processing space. The support unit 440 supports the substrate W in the processing space. The liquid supply unit 460 supplies the treatment solution onto the substrate W supported on the support unit 440. The treatment solution may be provided in a plurality of types and may be supplied sequentially onto the substrate W. The lifting unit 480 adjusts a relative height between the cup 420 and the support unit 440.

According to the example, the cup 420 includes a plurality of collection containers 422, 424, and 426. Each of the collection containers 422, 424, and 426 has a collection space of collecting the liquid used for the treating of the substrate. Each of the collection containers 422, 424, and 426 is provided in a ring shape surrounding the support unit 440. As the liquid processing process proceeds, the treatment solution scattered by the rotation of the substrate W enters the collection space through inlets 422a, 424a, and 426a of the respective collection containers 422, 424, and 426. According to the example, the cup 420 includes a first collection container 422, a second collection container 424, and a third collection container 426. The first collection container 422 is disposed to surround the support unit 440, the second collection container 424 is disposed to surround the first collection container 422, and the third collection container 426 is disposed to surround the second collection container 424. A second inlet 424a, which introduces the liquid into the second collection container 424, may be located above a first inlet 422a, which introduces the liquid into the first collection container 422, and a third inlet 426a, which introduces the liquid into the third collection container 426, may be located above the second inlet 424a.

The support unit 440 includes a support plate 442 and a driving shaft 444. A top surface of the support plate 442 may be provided in a generally circular shape, and may have a diameter larger than a diameter of the substrate W. In the center portion of the support plate 442, a support pin 442a is provided to support the rear surface of the substrate W, and the support pin 442a is provided with its upper end protruding from the support plate 442 so that the substrate W is spaced apart from the support plate 442 by a certain distance. A chuck pin 442b is provided to an edge of the support plate 442. The chuck pin 442b is provided to protrude upward from the support plate 442, and supports the lateral portion of the substrate W so that the substrate W is not separated from the support unit 440 when the substrate W is rotated. The drive shaft 444 is driven by a driver 446, is connected to the center of the bottom surface of the substrate W, and rotates the support plate 442 with respect to the central axis thereof.

In one example, the liquid supply unit 460 may include a nozzle 462. The nozzle 462 may deliver a treatment fluid to the substrate W. The treatment fluid may be a treatment solution. The treatment solution may be a chemical, rinse solution, or organic solvent. The chemical may be a chemical having the nature of strong acid or strong base. In addition, the rinse solution may be pure. Furthermore, the organic solvent may be isopropyl alcohol (IPA). Additionally, the liquid supply unit 460 may include a plurality of nozzles 462, each of which may supply a different type of treatment liquid. For example, one of the nozzles 462 may supply a chemical, another of the nozzles 462 may supply a rinse solution, and yet another of the nozzles 462 may supply an organic solvent. Further, the controller 30 may control the liquid supply unit 460 to supply an organic solvent from another one of the nozzles 462 to the substrate W after supplying a rinse solution from the other one of the nozzles 462. Thus, the rinse liquid supplied to the substrate W may be replaced with an organic solvent having low surface tension.

The lifting unit 480 moves the cup 420 in the vertical direction. By the vertical movement of the cup 420, a relative height between the cup 420 and the substrate W is changed. Accordingly, since the collection containers 422, 424, and 426 for collecting the treatment solution are changed according to the type of the liquid supplied to the substrate W, the liquids may be separated and collected. Unlike the description, the cup 420 may be fixedly installed, and the lifting unit 480 may move the support unit 440 in the vertical direction.

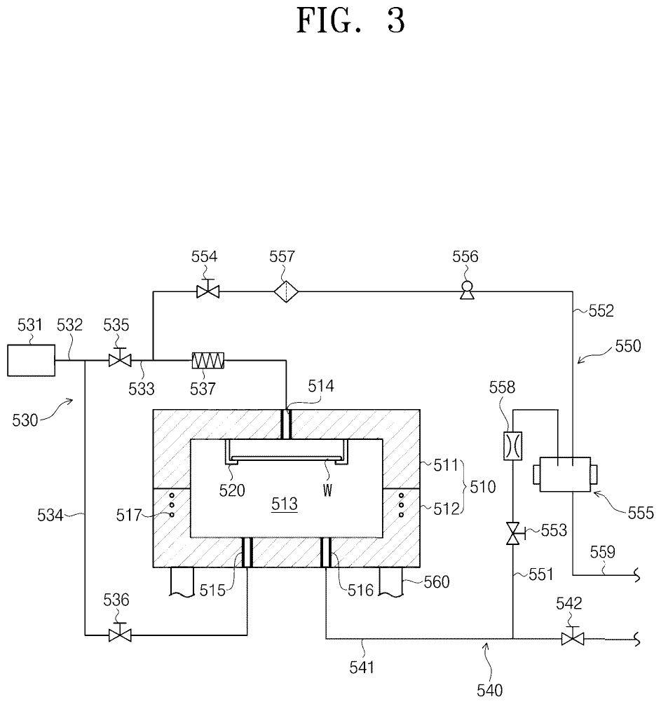

FIG. 3 is a diagram schematically illustrating a drying chamber of FIG. 1 according to the exemplary embodiment. Referring to FIG. 3, a drying chamber 500 according to the exemplary embodiment of the present invention may include a body 510, a support member 520, a fluid supply unit 530, a fluid exhaust unit 540, a fluid circulation unit 550, and a driver 560.

The body 510 may provide a processing space 513 where the substrate W is processed. The body 510 may include a first body 511 and a second body 512. The first body 511 and the second body 512 may be manufactured in a shape that may be combined with each other to define the processing space 513. The first body 511 may be the upper body and the second body 512 may be the lower body. Any one of the first body 511 and the second body 512 may be moved to open the processing space 513 or to close the processing space 513.

For example, the first body 511 may be stationary and the second body 512 may be moved in an up-and-down direction by the driver 560 that is moved by receiving power from a cylinder or motor. The second body 512 may be moved in a direction close to the first body 511 to close the processing space 513. Alternatively, the second body 512 may move in a direction away from the first body 511 to open the processing space 513.

Further, the first body 511 may be provided with a first supply port 514. The first supply port 514 may be a port formed by machining the first body 511. Alternatively, the first supply port 514 may be a port that is separately manufactured as a pipe shape and installed in a hole formed in the first body 511. The first supply port 514 may supply a drying fluid SCF to a center region of the top surface of the substrate W placed on the support member 520, which will be described later.

In addition, the second body 512 may be provided with a second supply port 515 and an exhaust port 516. The second supply port 515 and the second exhaust port 516 may be ports formed by machining the second body 512. Alternatively, the second supply port 515 and the exhaust port 516 may be ports that are separately manufactured in a pipe shape and installed in a hole formed in the second body 512. The second supply port 515 may supply the drying fluid SCF to the lower region of the processing space 513. The exhaust port 516 may exhaust the drying fluid SCF supplied to the processing space 513, and the treatment fluid IPA removed from the substrate W.

A heater 517 may be provided in the body 510. The heater 517 may be provided in the body 510 to increase the temperature of the processing space 513. The heater 517 may increase the temperature of the processing space 513 to a temperature at which the drying fluid SCF may remain supercritical. The heater 517 may be installed in both the first body 511 and the second body 512, or in any one of the first body 511 and the second body 512. FIG. 3 illustrates an example of the heater 517 being buried in the second body 512. The heater 517 may be variously modified to any known heater capable of raising the temperature of the processing space 513, such as a resistive coil.

The support member 520 may support the substrate W in the processing space 513. The support member 520 may be installed on the bottom surface of the first body 511, and may be configured to support an edge region of the substrate W. For example, one end of the support member 520 may be installed on the bottom surface of the first body 511 and the support member 520 may include a fixed portion that extends in an up and down direction, and a support portion that extends horizontally from the fixed portion. The fixed portion and the support portion may be provided as a single body, or they may be provided as separate bodies and be coupled together.

While the example described above illustrates the support member 520 being installed on the bottom surface of the first body 511, the support member 520 may also be provided in a form that is installed on the second body 512 rather than the support member 520.

The fluid supply unit 530 may supply a drying fluid (SCF to the processing space 513. The drying fluid SCF supplied by the fluid supply unit 530 to the processing space 513 may be carbon dioxide gas. The drying fluid SCF supplied by the fluid supply unit 530 to the processing space 513 may be supplied to the processing space 513 in a supercritical state, or may be supplied to the processing space 513 and changed from a gaseous state to a supercritical state.

The fluid supply unit 530 may include a fluid supply source 531, a main supply line 532, a first supply line 533, a second supply line 534, a first supply valve 535, a second supply valve 536, and a line heater 537.

The fluid supply source 531 may store and supply the drying fluid SCF. The fluid supply source 531 may be formed of a tank for storing the drying fluid SCF, a flow rate control device for withdrawing the drying fluid SCF from the tank at a set supply flow rate per unit time, and the like.

The main supply line 532 may be connected to the fluid supply source 531 and may be branched into a first supply line 533 and a second supply line 534. The first supply line 533 may supply the drying fluid SCF to an upper region of the processing space 513 (one example of a first region) via the first supply port 514. The second supply line 534 may supply the drying fluid SCF to a lower region of the processing space 513 (one example of a second region) via the second supply port 515.

The first supply valve 535, which may be an automatic valve (open/close valve), may be installed in the first supply line 533, and whether or not to supply the drying fluid SCF to the first supply port 514 may be selected depending on the opening or closing of the first supply valve 535. Additionally, the first supply line 533 may have the line heater 537 installed in the first supply line 533 to increase the temperature of the drying fluid SCF flowing in the first supply line 533, and the line heater 537 may increase the temperature of the drying fluid SCF to help the drying fluid SCF to be changed to the supercritical state or remain in the supercritical state. Additionally, the line heater 537 may be installed in the first supply line 533, but may be installed downstream of the first supply valve 535.

The second supply valve 536, which may be an automatic valve, is installed in the second supply line 534, and whether or not to supply drying fluid SCF to the second supply port 515 may be selected depending on the opening or closing of the second supply valve 536.

In the example described above, the first supply valve 535 and the second supply valve 536 are illustrated as being automatic valves, but without limitation, the first and second supply valves 535 and 536 may be provided as flow rate regulating valves capable of adjusting the supply flow rate of the drying fluid SCF.

The fluid exhaust unit 540 may exhaust the atmosphere of the processing space 513. The fluid exhaust unit 540 may include an exhaust line 541, and an exhaust valve 542. The exhaust line 541 may be connected to a pressure reducing device, such as a pump, not shown. The exhaust valve 542 may be an auto valve (open/close valve). The exhaust valve 542 is installed in the exhaust line 541 and may be installed downstream of the point where the exhaust line 541 is connected to a first circulation line 551 described later. Depending on the opening and closing of the exhaust valve 542, the atmosphere in the processing space 513 may be selectively exhausted.

The pressure in the processing space 513 may vary depending on the supply flow rate per unit time of the drying fluid SCF supplied by the fluid supply unit 530 and the exhaust flow rate per unit time of the fluid exhaust unit 540. Additionally, the degree to which the liquid phase of the treatment fluid IPA removed from the substrate W is dissolved in the drying fluid SCF may affect the pressure in the processing space 513. For example, when the amount of treatment fluid IPA dissolved in the drying fluid SCF increases, the pressure in the processing space 513 may increase by some amount.

In the following, the present invention will be described based on the case where the treatment fluid IPA removed from the substrate W via the drying fluid SCF is an organic solvent, such as isopropyl alcohol.

The fluid circulation unit 550 may circulate a mixed fluid in which a drying fluid SCF supplied by the fluid supply unit 530 and the treatment fluid IPA removed from the substrate W are mixed. The fluid circulation unit 550 may separate the drying fluid SCF and the treatment fluid IPA from the mixed fluid.

The drying fluid SCF separated from the mixed fluid may be supplied back into the first supply line 533. At least a portion of the treatment fluid IPA separated from the mixed fluid may be supplied back into the liquid treating chamber 400.

The fluid circulation unit 550 may include the first circulation line 551, a second circulation line 552, a first circulation valve 553, a second circulation valve 554, a separator 555, a fluid pressurizer 556, a filter 557, an orifice 558, and a liquid reuse line 559.

The first circulation line 551 may be connected to the fluid exhaust unit 540. For example, the first circulation line 551 may be connected to the exhaust line 541 and the separator 555 described later. The first circulation line 551 may be connected to the exhaust line 541, but may be connected to the exhaust line 541 upstream of the exhaust valve 542.

The second circulation line 552 may be connected to the fluid supply unit 530. For example, the second circulation line 552 may be connected to the first supply line 533 and the separator 555 described later. The second circulation line 551 may be connected to the first supply line 533, but may be connected to the point downstream of the first supply valve 535 and upstream of the line heater 537. Thus, the drying fluid SCF that is supplied back into the first supply line 533 via the second circulation line 552 may be reheated via the line heater 537 and supplied to the processing space 513.

The first circulation valve 553 may be an auto valve (open/close valve) and may be installed in the first circulation line 551. The second circulation valve 554 may be an auto valve (open/close valve) and may be installed in the second circulation line 552. Alternatively, the first and second circulation valves 553 and 554 may be provided as flow regulating valves.

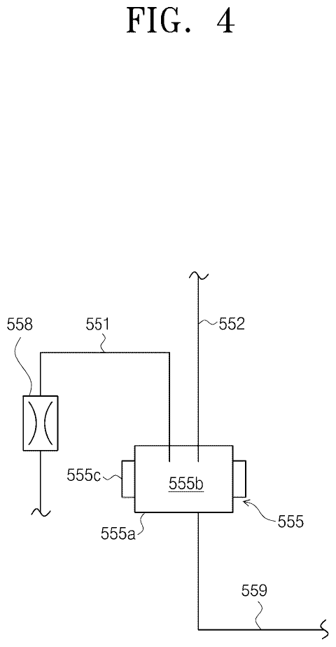

FIG. 4 is a diagram illustrating a structure of the separator of FIG. 3.

Referring to FIGS. 3 and 4, the separator 555 may be configured to separate the drying fluid SCF and the treatment fluid IPA from the mixed fluid circulated by the fluid circulation unit 550.

More specifically, the separator 555 may include a separation housing 555a providing a depressurized separation space 555b on the interior, and a cooling unit 555c provided on the exterior of the separation housing 555a.

Cooling airflow may flow in the cooling unit 555c. The cooling airflow flowing in the cooling unit 555c may lower the temperature of the separation space 555b provided by the separation housing 555a. In addition, the first circulation line 551 described above may be provided with the orifice 558 downstream of the first circulation valve 553. With the orifice 558 provided, the pressure difference due to the mixed fluid at the front end and the rear end of the orifice 558 may be kept relatively constant. For example, the pressure of the mixed fluid at the front end of the orifice 558 may be greater than the pressure of the mixed fluid at the rear end of the orifice 558.

The pressure of the mixed fluid is relatively low after passing through the rear end of the orifice 558. The mixed fluid with the reduced pressure may adiabatically expand as it is introduced into the separation space 555b of the separation housing 555a. More specifically, as the mixed fluid adiabatically expands from the flow path in the first circulation line 551, which has a relatively small cross-sectional area, into the separation space 555b, which has a relatively large cross-sectional area, the pressure of the mixed fluid may be lowered and the temperature may be lowered.

At this time, as the drying fluid SCF, which may be carbon dioxide contained in the mixed fluid, becomes less soluble in the treatment fluid IPA, which may be isopropyl alcohol, very quickly, the drying fluid SCF and the treatment fluid IPA are separated in the separation space 555b. Further, because the density of the drying fluid SCF is smaller than the density of the treatment fluid IPA, in the separation space 555b, the drying fluid SCF is collected in the upper region of the separation space 555b and the treatment fluid IPA is collected in the lower region of the separation space 555b.

The drying fluid SCF collected in the upper region of the separation space 555b may be delivered to the first supply line 533 via the second circulation line 552 connected to the upper portion of the separation housing 555a, and the treatment fluid IPA collected in the lower region of the separation space 555b may be delivered to the liquid treating chamber 400 described above via the liquid reuse line 559 connected to the lower portion of the separation housing 555a.

Referring again to FIG. 3, the fluid circulation unit 550 of the present invention may further include the fluid pressurizer 556. The fluid pressurizer 556 may increase the flow velocity of the drying fluid SCF while withdrawing the drying fluid SCF separated in the separation space 55b from the separation space 555b. The fluid pressurizer 556 may be a gas booster. As previously described, it is necessary for the drying fluid SCF to be delivered to the substrate W in a supercritical state. Further, it is necessary to maintain the state of the drying fluid SCF in a supercritical state or a state similar to a supercritical state (i.e., a state suitable for performing a treatment process on the substrate W) in order to minimize the generation of particles within the line through which the drying fluid SCF flows.

As previously described, as the mixed fluid is depressurized/cooled in the separator 555, the drying fluid SCF is also depressurized/cooled. As such, the drying fluid SCF may not be able to maintain a supercritical state. Therefore, in the present invention, the fluid pressurizer 556 may be installed in the second circulation line 552 to increase the pressure of the drying fluid SCF that has been reduced in the separator 555 to a pressure suitable for maintaining the supercritical state (e.g., about 150 Bar).

The filter 557 may be installed in the second circulation line 552, but may be installed downstream of the fluid pressurizer 556. The filter 557 may be configured as a particle filter to filter particles generated during the process of separating the drying fluid SCF and the treatment fluid IPA from the mixed fluid or as the drying fluid SCF flows along the lines. The filter 557 may also include a chemical filter capable of removing the treatment fluid IPA material that may be partially contained in the drying fluid SCF.

The liquid reuse line 559 is connected to the lower portion of the separation housing 555a, and is capable of withdrawing and recovering the treatment fluid IPA that is separated in the separation space 555b of the separation housing 555a. The treatment fluid IPA withdrawn from the separator 555 by the liquid reuse line 559 may be supplied back into the liquid treating chamber 400.

In this case, the liquid reuse line 559 may be directly connected to the liquid treating chamber 400 or may be indirectly connected via a liquid supply tank that supplies treatment liquid to the liquid treating chamber 400. In short, it should be understood that the supply of the separated treatment fluid IPA to the liquid treating chamber 400 by the liquid reuse line 559 includes supplying the treatment fluid IPA directly to the liquid treating chamber 400, or supplying the treatment fluid IPA indirectly through another configuration.

Further, as described above, the substrate processing apparatus may include the plurality of liquid treating chambers 400, and the liquid reuse line 559 may be configured to supply the separated treatment fluid IPA to any one selected from the plurality of liquid treating chambers 400. The liquid treating chamber 400 may also mix the reused treatment fluid IPA and the unused treatment fluid IPA that are introduced through the liquid reuse line 559 and supply the substrate W with the mixed fluid. Alternatively, in the liquid treating chamber 400, the reused treatment fluid IPA may be utilized as the early treatment fluid supplied to the substrate W, and the unused treatment fluid IPA may be utilized as the late treatment fluid.

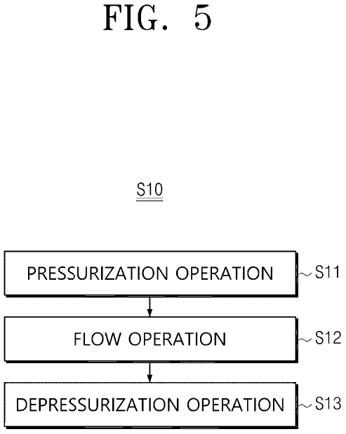

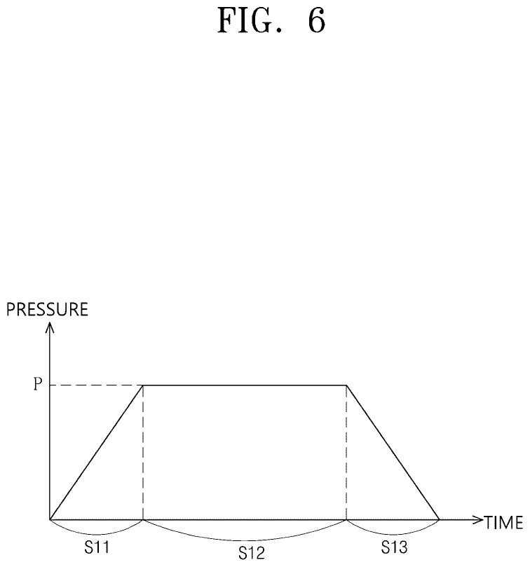

FIG. 5 is a flow chart illustrating a substrate processing method according to an exemplary embodiment of the present invention, and FIG. 6 is a graph illustrating an example of a processing space pressure change during a pressurization operation, a flow operation, and a depressurization operation of FIG. 5.

Referring to FIGS. 5 and 6, a substrate processing method according to an exemplary embodiment of the present invention may include, after performing a liquid treatment operation in which a treatment fluid IPA is supplied to the substrate W in a liquid treating chamber 400 to treat the substrate W, a drying operation S10 of supplying a drying fluid SCF onto the substrate W in a drying chamber 500 and removing the treatment fluid IPA residual on the substrate W.

The drying operation S10 according to the exemplary embodiment of the present invention may include a pressurization operation S11, a flow operation S12, and a depressurization operation S13.

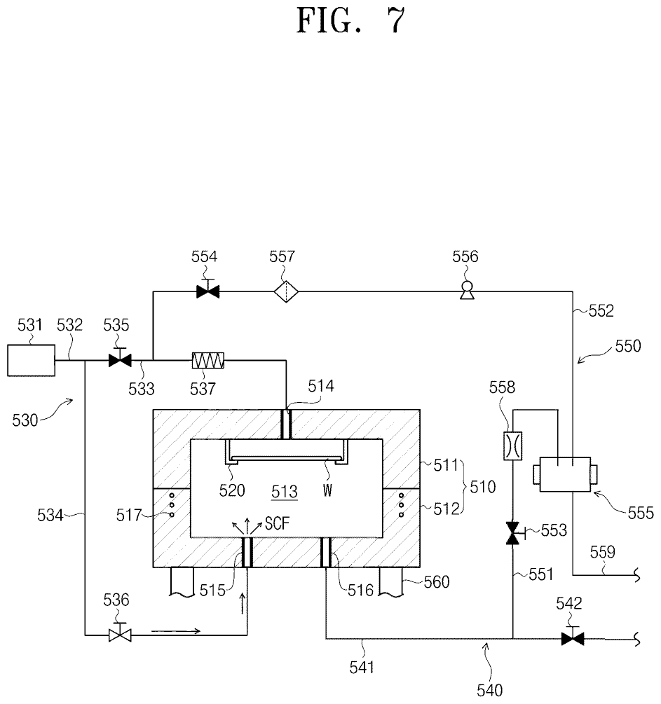

In FIGS. 7 to 9 and FIGS. 11 and 12, open valves are shown in white and closed valves are shown in black.

FIG. 7 is a diagram illustrating a view of the drying chamber performing the pressurization operation of FIG. 6.

Referring to FIGS. 5 to 7, the pressurization operation S11 may be an operation to increase the pressure in the processing space 513 to a set pressure P. In the pressurization operation S11, the second supply port 515 may supply the drying fluid SCF to increase the pressure in the processing space 513 to a set pressure P, for example, a pressure equal to or greater than a threshold pressure at which the drying fluid SCF is phase-changed to a supercritical state. The set pressure may be 150 Bar.

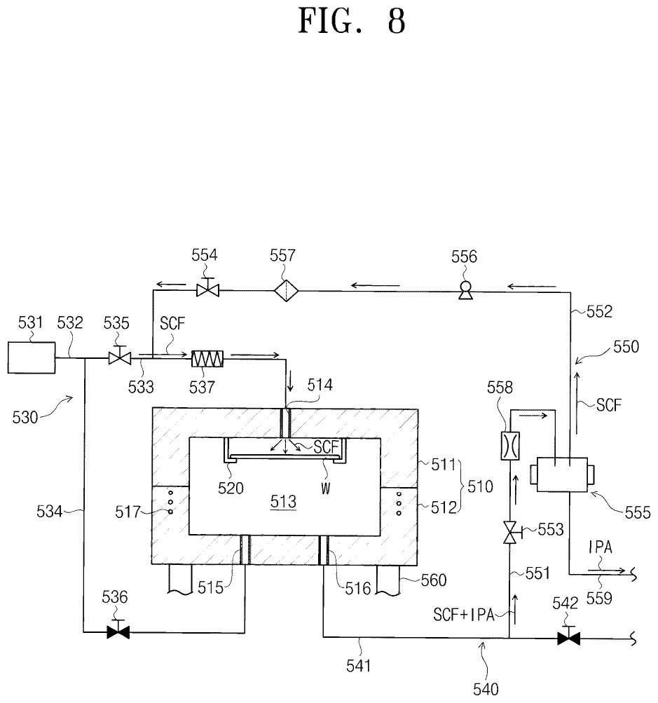

FIG. 8 is a diagram illustrating a view of the drying chamber performing the flow operation of FIG. 6.

Referring to FIGS. 5, 6, and 8, the flow operation S12 may be an operation of causing the drying fluid SCF supplied to the processing space 513 to flow while maintaining the pressure in the processing space 513 at the set pressure P (i.e., matching the supply flow rate to the exhaust flow rate per unit time) to remove any remaining treatment fluid IPA on the substrate W. In the flow operation S12, the first supply port 514 may supply the drying fluid SCF. In addition, in the flow operation S12, the fluid circulation unit 550 may exhaust the atmosphere of the processing space 513 via the exhaust line 541.

The drying fluid SCF separated from the mixed fluid via the fluid circulation unit 550 may be re-supplied to the first supply line 533. That is, at least a portion of the drying fluid SCF supplied to the processing space 513 may be reused drying fluid SCF and another some may be unused drying fluid SCF supplied from the fluid supply source 531. Accordingly, the amount of drying fluid SCF consumed may be minimized.

Additionally, the reused drying fluid SCF may be pressurized and warmed as it passes through the fluid pressurizer 556 and the line heater 537 and be supplied to the processing space 513 in a supercritical state or in a state just prior to transitioning to a supercritical state.

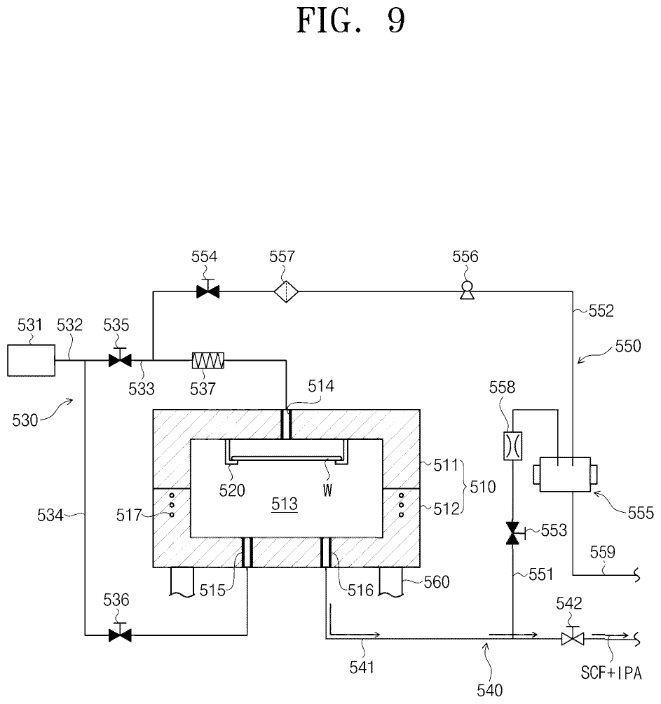

FIG. 9 is a diagram illustrating a view of the drying chamber performing the depressurization operation of FIG. 5.

Referring to FIGS. 5, 6, and 9, the depressurization operation S13 may include reducing the pressure in the processing space 513. In the depressurization operation S13, the pressure in the processing space 513 may be reduced from the set pressure P to normal pressure without circulating the mixed fluid in the fluid circulation unit 550.

As shown in FIG. 9, in the depressurization operation S13, some of the treatment fluid IPA may be discarded rather than reused via the exhaust line 541, but since most of the treatment fluid IPA was removed from the substrate W in the flow operation S12 and separated via the separator 555, the amount of treatment fluid IPA discarded in the depressurization operation S13 may be extremely small.

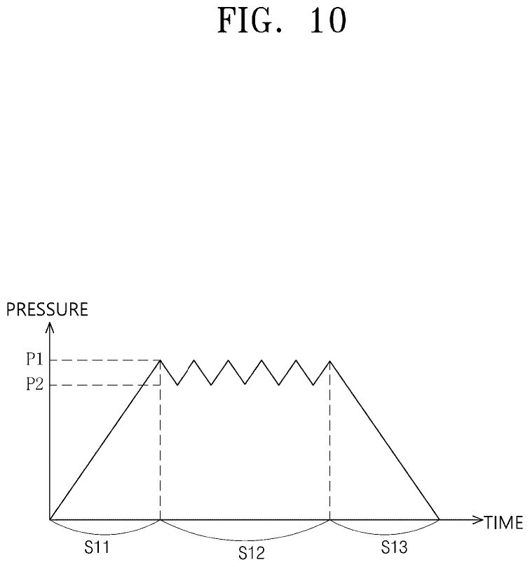

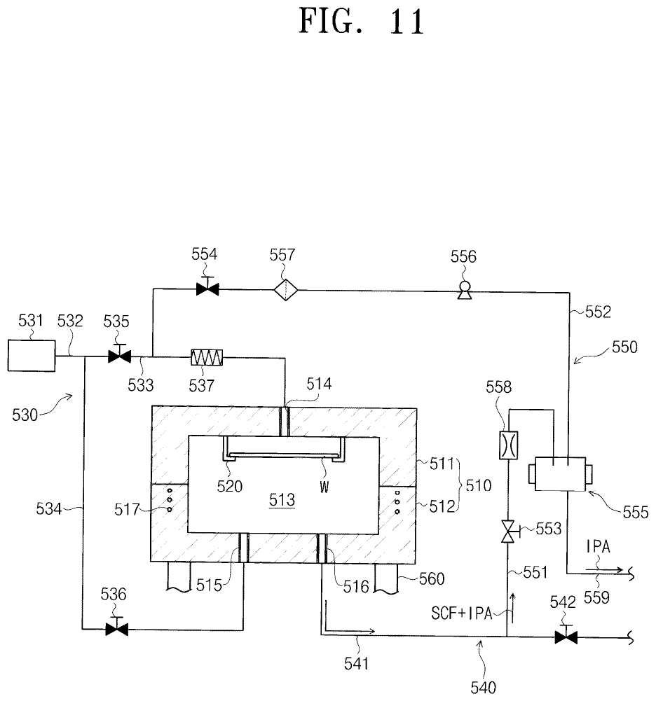

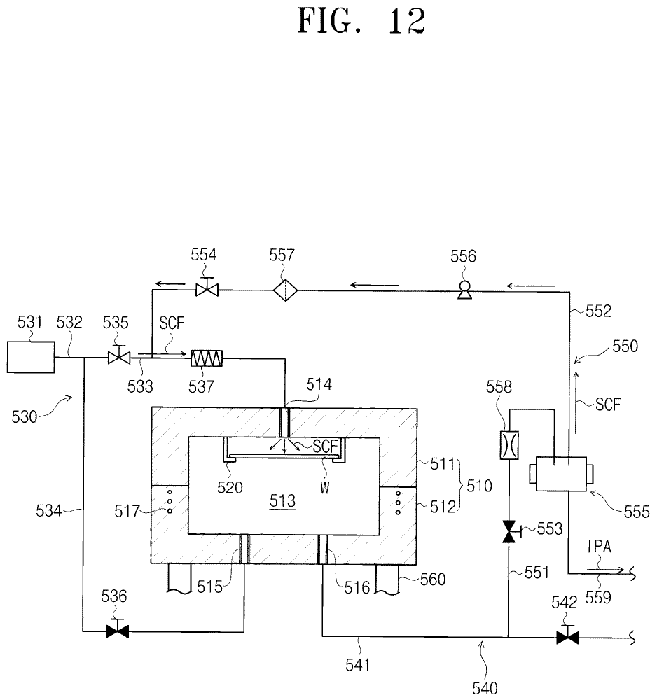

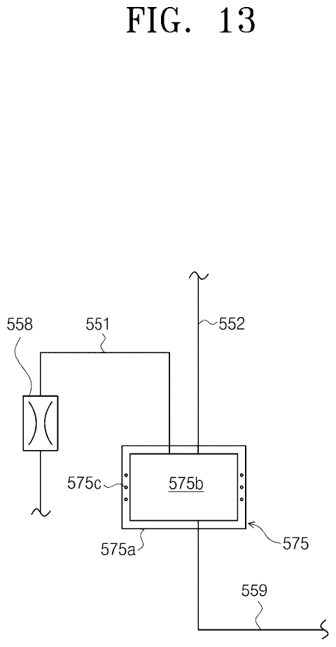

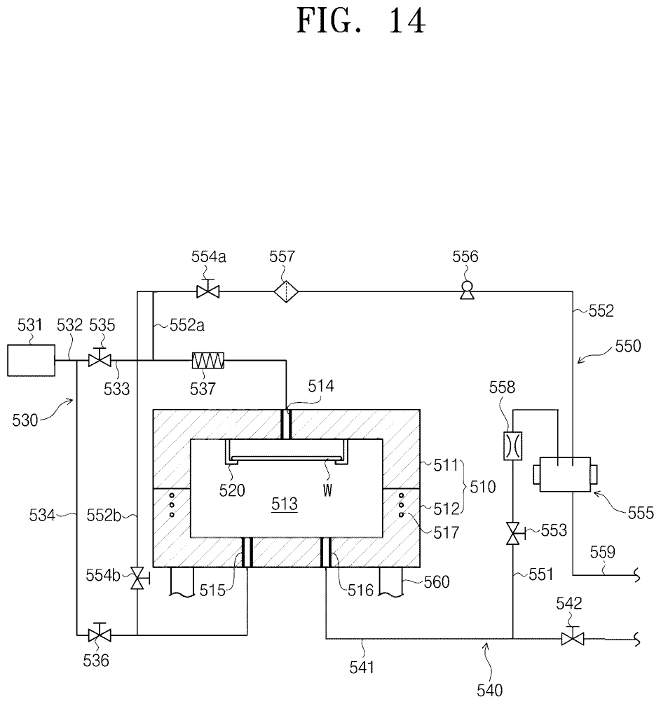

FIG. 10 is a graph showing different examples of processing space pressure changes during the pressurization operation, the flow operation, and the depressurization operation of FIG. 5, FIGS. 11 and 12 are diagrams a view of the drying chamber performing the flow operation of FIG. 10, and FIG. 13 is a diagram illustrating a separator according to another exemplary embodiment of the present invention.

In the above example, the present invention has been described based on the case where the pressure of the processing space 513 is maintained at the set pressure P as an example, but the present invention is not limited thereto. For example, as shown in FIG. 10, in the flow operation S12, the pressure in the processing space 513 may be pulsed between a first set pressure P1 and a second set pressure P2 that is lower than the first set pressure. Both the first set pressure P1 and the second set pressure P2 may be pressures higher than the threshold pressure.

When the pressures of the processing space 513 is depressurized from the first set pressure P1 to the second set pressure P2, the first circulation valve 553 may be opened, and the first and second supply valves 535 and 536, the second circulation valve 554, and the exhaust valve 542 may be closed.

When the pressures of the processing space 513 is pressurized from the second set pressure P2 to the first set pressure P1, the second circulation valve 554 and the first supply valve 535 may be open, and the second supply valve 536, the first circulation valve 553, and the exhaust valve 542 may be closed.

In the example, the present invention has been described based on the case where the separator 555 is an air-cooled separator with cooling air flowing through the cooling unit 555c of the separator 555 as an example, but the present invention is not limited thereto.

For example, as shown in FIG. 13, a separator 575 according to another exemplary embodiment includes a cooling unit 575c provided in a separation housing 575a that provides a separation space 575b, and the cooling unit 575c may be provided in the form of a cooling flow path. That is, cooling water may flow through the cooling unit 575c. In this case, the separator 575 may be a water-cooled separator.

In the above example, the present invention has been described based on the case where the second circulation line 552 is connected only to the first supply line 533 as an example, but the present invention is not limited thereto. For example, the other end of the second circulation line 552 may be branched into a second-first circulation line 552a and a second-second circulation line 552b. The branched second-first circulation line 552a and second-second circulation line 552b may be connected to the first supply line 533 and the second supply line 534, respectively. Further, the second circulation line 554 may be equipped with a second-first circulation valve 554a and the second-second circulation line 552b may be equipped with a second-second circulation valve 554b.

In FIG. 4, the present invention has been described based on the case where the second-first circulation valve 554a is installed upstream of the branched point as an example, but the present invention is not limited thereto, and the second-first circulation valve 554a may also be installed in the second-first circulation line 552a.

In the example described above, the present invention has been described based on the case where all of the mixed fluid that is exhausted from the processing space 513 in the depressurization operation S13 is exhausted through the exhaust line 541 as an example, but the present invention is not limited thereto.

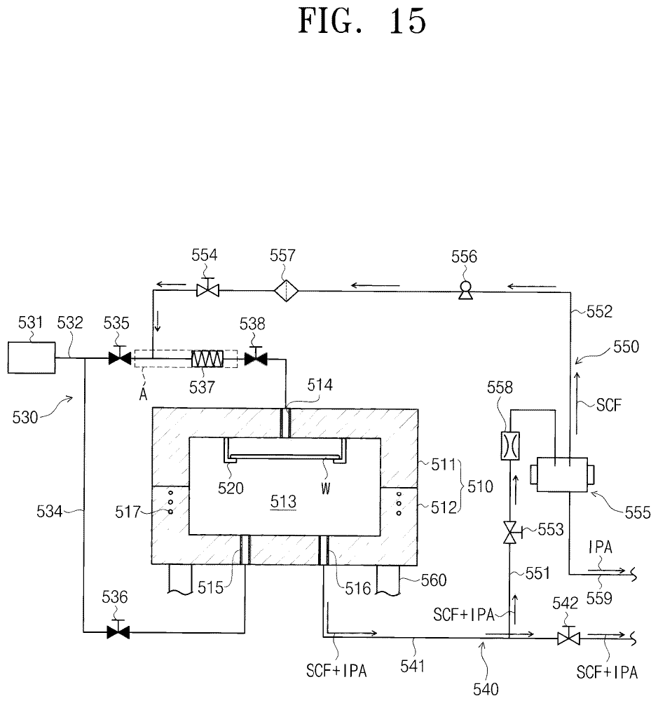

For example, as shown in FIG. 15, the first supply line 533 may further include a third supply valve 538 installed downstream of the first supply valve 535 and the line heater 537. A portion of the mixed fluid exhausted from the processing space 513 in the depressurization operation S13 may be exhausted to the outside of the drying chamber 500 via the exhaust line 541, and another portion may be supplied with drying fluid SCF via the fluid circulation unit 550 to region A shown in FIG. 15. The drying fluid remaining in the region A may maintain the condition of the first supply line 533 in a state similar to a process state until the next substrate W is loaded.

In the example described above, the present invention has been described based on the case where the line heater 537 is provided in the first supply line 533 as an example, but the present invention is not limited thereto. For example, the line heater 537 may also be installed in the second supply line 534.

In the example described above, the present invention has been described based on the case where the first body 511 is an upper body positioned at the top and the second body 512 is a lower body positioned at the bottom, but the present invention is not limited thereto. For example, the first body 511 and the second body 512 may be arranged along a left-right direction rather than an up-down direction. The second body 512 may be provided stationary, and the first body 511 is laterally movable. The first body 511 may be provided with a support member for supporting the substrate W in a horizontal direction, such that the substrate W may be loaded into and unloaded from the processing space 513 in a drawer-like manner.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

1. An apparatus for processing a substrate, the apparatus comprising:
a body providing a processing space;
a supply line for supplying a drying fluid that removes a treatment fluid on a substrate supported in the processing space;
an exhaust line for exhausting an atmosphere of the processing space; and
a fluid circulation unit connected with the exhaust line and the supply line,
wherein the fluid circulation unit includes:
a separator for separating the treatment fluid and the drying fluid from a mixed fluid in which the treatment fluid and the drying fluid exhausted from the processing space are mixed; and
a liquid reuse line connected to the separator, and for withdrawing, from the separator, the treatment fluid separated from the separator.

2. The apparatus of claim 1, further comprising:
a liquid treating chamber for supplying the treatment fluid to the substrate,
wherein the liquid reuse line is connected to the liquid treating chamber.

3. The apparatus of claim 1, wherein the fluid circulation unit includes:
a first circulation line connected to the exhaust line and the separator; and
a second circulation line connected with the separator and the supply line, and
a cross-sectional area of a separation space provided by the separator is greater than a cross-sectional area of the first circulation line.

4. The apparatus of claim 3, wherein the separator includes:
a separation housing providing the separation space; and
a cooling unit provided in the separation housing.

5. The apparatus of claim 4, wherein a cooling airflow or cooling water flows in the cooling unit.

6. The apparatus of claim 3, wherein in the first circulation line, an orifice is installed to maintain a constant pressure difference between a front end and a rear end.

7. The apparatus of claim 3, wherein the first circulation line is connected to the exhaust line upstream of an exhaust valve installed on the exhaust line.

8. The apparatus of claim 3, wherein in the second circulation line, a fluid pressurizer is installed for withdrawing and pressurizing the drying fluid separated from the mixed fluid in the separation space.

9. The apparatus of claim 3, wherein in the supply line, a heater is installed to heat the drying fluid supplied to the processing space, and
the second circulation line is connected to the supply line upstream of the heater.

10. The apparatus of claim 3, wherein the supply line includes:
a first supply line for supplying the drying fluid to a first region of the processing space; and
a second supply line for supplying the drying fluid to a second region of the processing space at a location different from the first region of the processing space, and
the second circulation line is branched to be connected to the first supply line and the second supply line, respectively.

11.-17. (canceled)

18. An apparatus for processing a substrate, the apparatus comprising:
a plurality of liquid treating chambers for liquid-treating a substrate by supplying a treatment solution to the substrate; and
a drying chamber for removing the treatment solution supplied to the substrate from any one of the plurality of liquid treating chambers,
wherein the drying chamber includes:
a body providing a processing space;
a supply line for supplying a drying fluid that removes the treatment solution on the substrate supported in the processing space;
an exhaust line for exhausting an atmosphere of the processing space; and
a fluid circulation unit connected with the exhaust line and the supply line, and
the fluid circulation unit includes:
a separator for separating the treatment solution and the drying fluid from a mixed fluid in which the treatment solution and the drying fluid exhausted from the processing space are mixed, the separator including: a separation housing providing the separation space; and a cooling unit provided on an exterior of the separation housing; and
a liquid reuse line connected to the separator, and for withdrawing the separated treatment solution from the separator and supplying the withdrawn treatment solution to any of the plurality of liquid treating chambers, and connected to a lower portion of the separation housing.

19. The apparatus of claim 18, wherein the fluid circulation unit further includes:
a first circulation line connected with the exhaust line and the separator;
a second circulation line connected with the separator and the supply line and connected to an upper portion of the separation housing;
an orifice installed in the first circulation line, and maintaining a constant pressure difference between a front end and a rear end;
a fluid pressurizer installed in the second circulation line, and for withdrawing and pressurizing the drying fluid separated from the mixed fluid in the separation space; and
a filter installed downstream of the fluid pressurizer in the second circulation line.

20. The apparatus of claim 19, wherein in the supply line, a heater is installed to heat the drying fluid supplied to the processing space, and
the second circulation line is connected to the supply line upstream of the heater.
